(19) United States
(12) Patent Application Publication
(10) Pub. No.: US 2016/0172190 A1
(43) Pub. Date: Jun. 16, 2016

(54) GATE OXIDE FORMATION PROCESS

(71) Applicant: UNITED MICROELECTRONICS CORP., Hsin-Chu City (TW)

(72) Inventors: Hung-Lin Shih, Hsinchu City (TW); Chueh-Yang Liu, Tainan City (TW); Shao-Wei Wang, Taichung City (TW); Che-Hung Huang, Hsinchu City (TW); Po-Hua Jen, Hsinchu City (TW); Shih-Hao Su, Kaohsiung City (TW)

(21) Appl. No.: 14/571,249

(22) Filed: Dec. 15, 2014

(51) Int. Cl. H01L 21/02; H01L 21/283

(52) U.S. Cl. CPC H01L 21/02252; H01L 21/283; H01L 21/02181; H01L 21/0223; H01L 21/02255; H01L 21/02337; H01L 21/02343

(57) ABSTRACT

A gate oxide formation process includes the following steps. A first gate oxide layer is formed on a substrate. The first gate oxide layer is thinned to a first predetermined thickness. The first gate oxide layer is then thickened to a second predetermined thickness, to thereby form a second gate oxide layer.

### BACKGROUND OF THE INVENTION

1. Field of the Invention

The present invention relates generally to a gate oxide formation process, and more specifically to a gate oxide formation process which forms a gate oxide layer by thinning and thickening processes.

2. Description of the Prior Art

With advances in semiconductor technology, integrated circuits (IC′) with multi-functional circuit modules composed of a large number of transistors and/or other semiconductor devices integrated on a silicon die are becoming ever more popular. In integrated VLSI and ULSI circuits, the number of transistors and/or other semiconductor devices included is huge and the devices are densely packed together. Therefore, isolation structures are incorporated between adjacent transistors/devices to prevent short circuits from occurring. The most commonly used isolation structures may include field oxide isolation, and trench isolation such as shallow trench isolation (STI).

In an integrated circuit, different circuit modules and/or transistors and other devices in the same chip may operate indifferent voltage regimes. In an integrated switching-mode power supply, which may include a power transistor and a control circuit for switching the power transistor ON and OFF to convert a supply voltage into a desired output voltage, the power transistor may have an operating voltage much higher than an operating voltage of transistors constituting the control circuit. In order to have an area-efficient high voltage device with low voltage control devices fabricated on a same die, gate insulation layers with different thicknesses are required. When the high-voltage driving elements and the low-voltage driving elements are embodied simultaneously, a thick gate oxide film for high voltage and a thin gate oxide film for low voltage are required.

### SUMMARY OF THE INVENTION

The present invention provides a gate oxide formation process, which thins and thickens a gate oxide layer to a predetermined thickness.

The present invention provides a gate oxide formation process including the following steps. A first gate oxide layer is formed on a substrate. The first gate oxide layer is thinned to a first predetermined thickness. The first gate oxide layer is then thickened to a second predetermined thickness, thereby forming a second gate oxide layer.

According to the above, the present invention provides a gate oxide formation process, which forms a first gate oxide layer on a substrate, thins the first gate oxide layer to a first predetermined thickness, and then thickens the first gate oxide layer to a second predetermined thickness. Thereby, a second gate oxide layer having the second predetermined thickness is formed.

Since at least a part of the first gate oxide layer must remain after the thinning process; that is, the first predetermined thickness must be larger than zero, native oxide will not be generated and divots of isolation structures contacting the remaining first gate oxide layer will not occur. Furthermore, the second predetermined thickness can be adjusted and controlled precisely, leading to better accuracy and uniformity. Equivalent oxide thickness (EOT) and leakage current density (Jg) can also be reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 schematically depict a cross-sectional view of agate oxide formation process according to a preferred embodiment of the present invention.

FIGS. 9-10 schematically depict a cross-sectional view of a gate oxide formation process according to an embodiment of the present invention.

### DETAILED DESCRIPTION

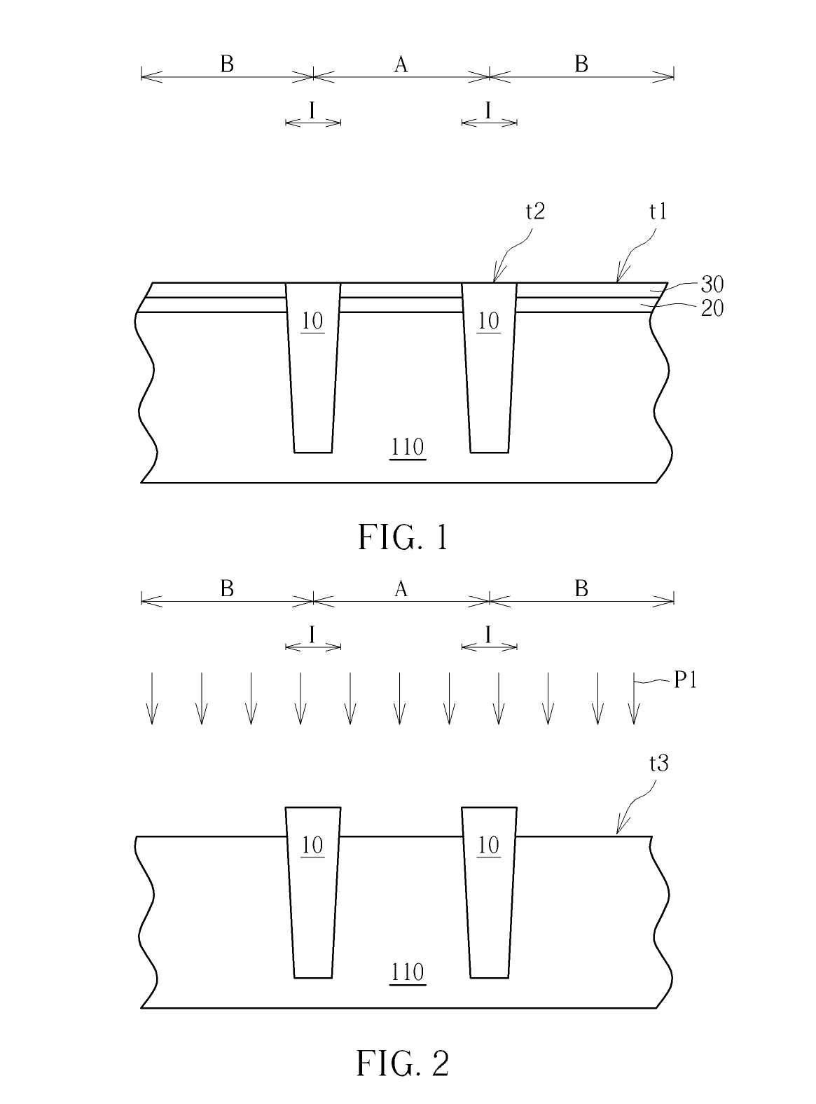

FIGS. 1-8 schematically depict a cross-sectional view of agate oxide formation process according to a preferred embodiment of the present invention. As shown in FIG. 1, a substrate 110 is provided. The substrate 110 may be a semiconductor substrate such as a silicon substrate, a silicon-containing substrate, or a silicon-on-insulator (SOI) substrate etc. Isolation structures 10 are located in the substrate 110. The isolation structures 10 may be shallow trench isolation (STI) structures, which may be formed by a shallow trench isolation (STI) process, but are not limited thereto.

The substrate 110 is divided into a first area A and two second areas B by the isolation structures 10, and the first area A and the two second areas B are isolated from the isolation structures 10. The number of the isolation structures 10, the first area A and the two second areas B are not restricted thereto, and depend upon practical requirements. The first area A is a low voltage area while the second areas B are high voltage areas. In this embodiment, the first area A is a logic area while the second areas B are input/output areas, but this is not limited thereto. The present invention is applied to form planar components such as planar transistors in this embodiment, but the present invention can also be applied to form non-planar components such as non-planar transistors or fin field-effect transistors (FinFET) in another embodiment, so the substrate 110 may include at least a fin-shaped structure in the first area A on and the second areas B.

A pad oxide layer 20 and a pad nitride layer 30 are sequentially located on the substrate 110, wherein a top surface t1 of the pad nitride layer 30 trims top surfaces t2 of the isolation structures 10.

The method of forming the isolation structures 10, the pad oxide layer 20 and the pad nitride layer 30 may include the following. A pad oxide layer (not shown) and a pad nitride layer (not shown) may blanketly cover the substrate 110. After the pad oxide layer and the pad nitride layer are sequentially formed on the substrate 110, a lithography process may be performed to form a photoresist layer (not shown) and define insulating areas I. The pad nitride layer and the pad oxide layer are patterned and the substrate 110 is etched to form trenches (not shown) by using the photoresist layer as a mask for etching once or a plurality of times. The photoresist layer is then removed to form the pad oxide layer 20 and the pad nitride layer 30. The depths of the trenches may be between 300 nm and 700 nm, depending upon a desired formed structure. A liner (not shown) may be selectively formed on the inner sides of the trenches to eliminate damage caused during etching, wherein the liner may be an oxide layer, and may be formed by methods such as a thermal oxidation method. Thereafter, the isolation structures (not shown) are filled in the trenches by methods such as chemical vapor deposition (CVD) or high aspect ratio process (HARP). The excess material of the isolation structure may be removed by applying chemical-mechanical polishing (CMP) and using the pad nitride layer 30 as a polish stop layer, to form the isolation structures 10 having the flat top surface t2.

The pad nitride layer 30 and the pad oxide layer 20 are then removed completely by using, for example, hot phosphoric acid and dilute hydrofluoric acid (DHF) for enabling following processes to be performed, as shown in FIG. 2. The substrate 110 including the first area A and the second areas B is exposed. Preferably, a cleaning process P1 may be performed to clean a top surface t3 of the substrate 110. The cleaning process P1 may include an ozone containing process, a dilute hydrofluoric acid process, a standard clean 1 (SC1) process, a standard clean 2 (SC2) process or a combination thereof, depending upon practical requirements.

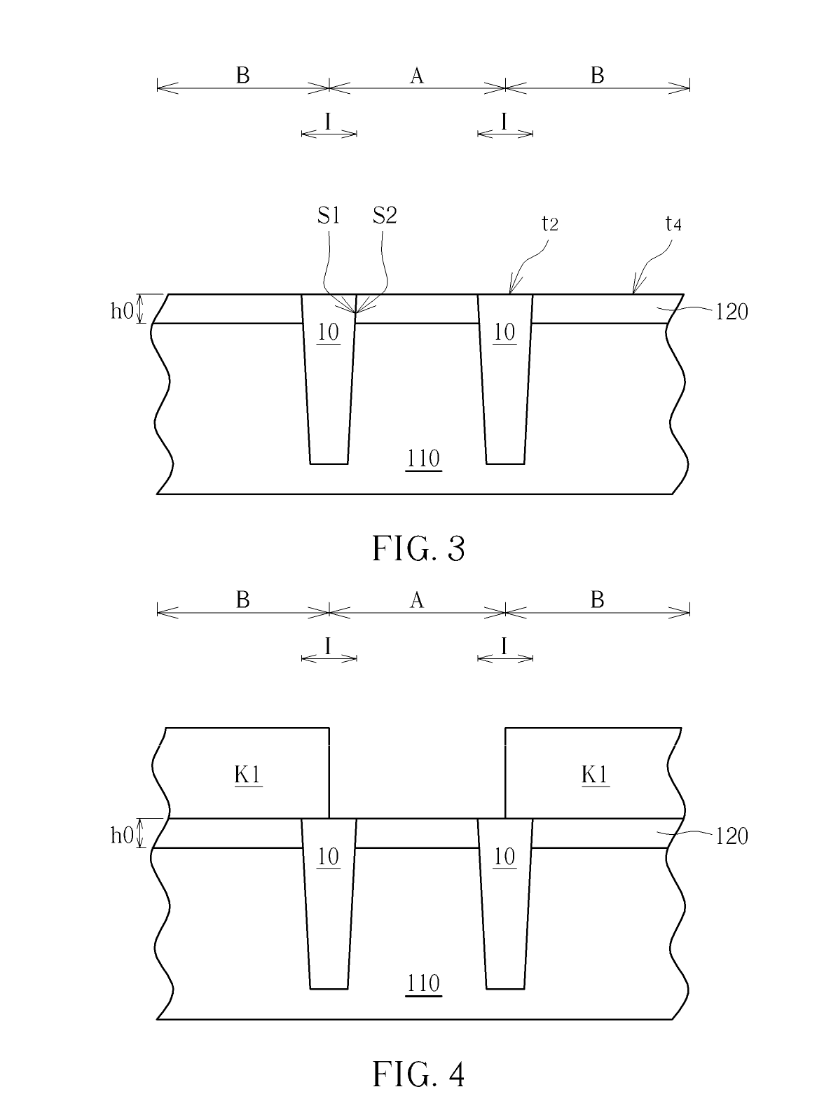

As shown in FIG. 3, a first gate oxide layer 120 is formed on the substrate 110 of the first area A as well as the second areas B. In this embodiment, the isolation structures 10 protrude from the substrate 110; the first oxide layer 120 has a thickness h0 and has a top surface t4 trimming with the top surfaces t2 of the isolation structures 10. Sidewalls S1 of the first gate oxide layer 120 contact sidewalls S2 of the isolation structures 10. The first oxide layer 120 may be formed by a thermal oxide process. Preferably, the first gate oxide layer 120 is formed by an in-situ steam generation (ISSG) process, which may utilize imported hydrogen gas and oxygen gas, but this is not limited thereto.

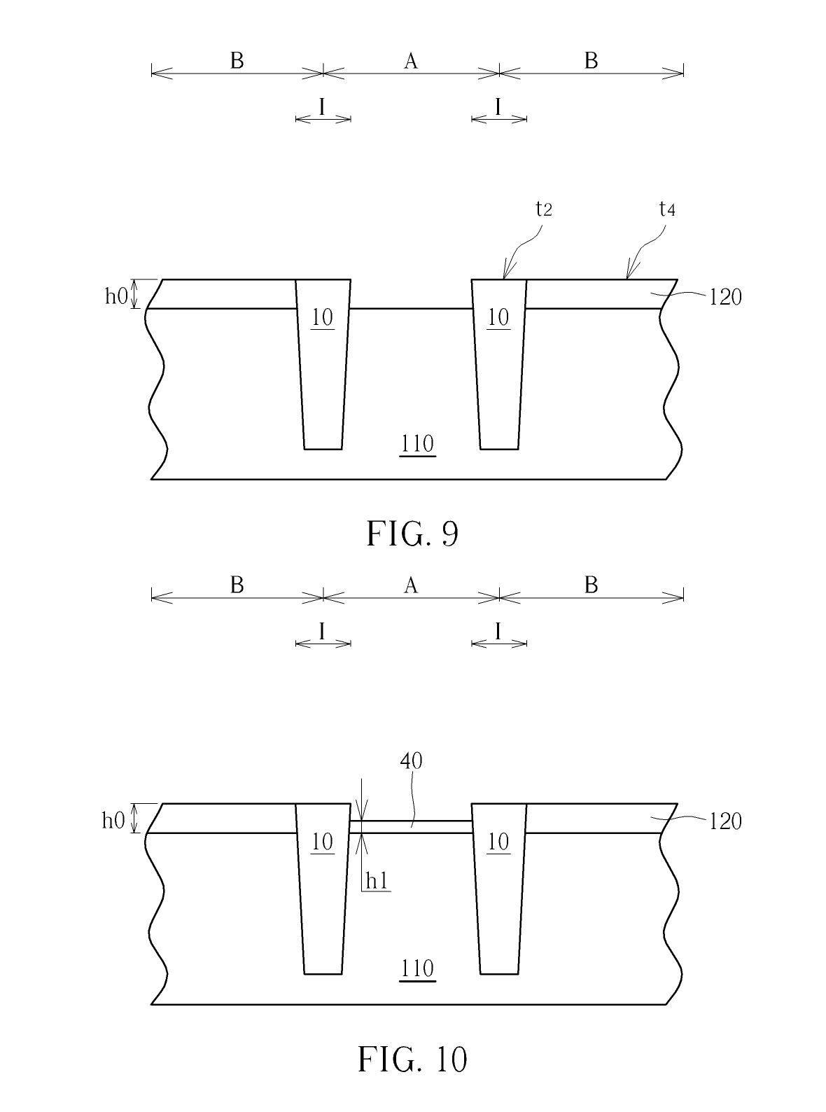

After forming the first gate oxide layer 120 having a same thickness h0 in the first area A and the second areas B, methods for forming gate oxide layers having different thicknesses in the first area A and the second areas B are provided in the following. FIGS. 9-10 schematically depict a cross-sectional view of a gate oxide formation process according to an embodiment of the present invention. The first gate oxide layer 120 of the first area A is removed completely and the substrate 110 of the first area A is exposed, as shown in FIG. 9. Then, a second gate oxide layer 40 having a predetermined thickness h1 is formed on the substrate 110 of the first area A. It is noted that the thickness h0 of the first oxide layer 120 is different from the predetermined thickness h1 of the second gate oxide layer 40. More precisely, the predetermined thickness h1 of the second gate oxide layer 40 is thinner than the thickness h0 of the first oxide layer 120 because the first area A is a low voltage area while the second areas B are high voltage areas.

A native oxide layer is inevitably formed on the substrate 110 as the substrate 110 of the first area A is exposed due to the first gate oxide layer 120 of the first area A being completely removed, as shown in FIG. 9. Film quality of the native oxide layer is bad and loose. A thickness of the native oxide layer may approach 6 angstroms; therefore, a cleaning process removing the native oxide layer is required before the second gate oxide layer 40 is formed. The cleaning process may be an etching process having an etchant of dilute hydrofluoric acid (DHF), a standard clean 1 (SC1) or a standard clean 2 (SC2) process etc. As a result, the processing steps become complex and may lead to problems. Furthermore, divots of the isolation structures 10 occur because of the over-etching while removing the first gate oxide layer 120 and performing the cleaning process.

Therefore, a preferred embodiment is presented in the following. Please refer to FIGS. 4-5. The first gate oxide layer 120 of the first area A is thinned down to a first predetermined thickness h2 after the first gate oxide layer 120 is formed as shown in FIG. 3, wherein the first predetermined thickness h2 must be larger than zero. That is, there must be a part of the first gate oxide layer 120 reserved. More precisely, as shown in FIG. 4, a photoresist (not shown) is deposited and patterned to form a patterned photoresist K1, to expose the first gate oxide layer 120 of the first area A. As shown in FIG. 5, only the first gate oxide layer 120 of the first area A is thinned by performing an etching process P2. Preferably, the etching process P2 includes an etchant of dilute hydrofluoric acid (DHF); the processing time of the etching process P2 is in a range of 60˜80 seconds, preferably 70 seconds, but not limited thereto. As a result, a first gate oxide layer 120a of the first area A is formed while the first gate oxide layer 120 of the second areas B is maintained. In a preferred embodiment, the first gate oxide layer 120a of the first area A has the first predetermined thickness h2 of 5˜10 angstroms.

It is emphasized that the first predetermined thickness h2 must be larger than zero. Therefore, said native oxide layer will not be generated because the substrate 110 is not exposed and is covered by the first gate oxide layer 120a. The divots of the isolation structures 10 will also not occur due to the substrate 110 and the bottom parts of the isolation structures 10 being covered by the first gate oxide layer 120a so they cannot be etched by the over-etching while removing the first gate oxide layer 120 and performing the cleaning process.

A cleaning process P3 may be optionally performed on the first gate oxide layer 120a of the first area A and the first gate oxide layer 120 of the second areas B to further clean the first gate oxide layer 120a/120 before the first gate oxide layer 120a is thickened in later processes. The cleaning process P3 may be an etching process having an etchant of dilute hydrofluoric acid (DHF), a standard clean 1 (SC1) or a standard clean 2 (SC2) process, but this is not limited thereto.

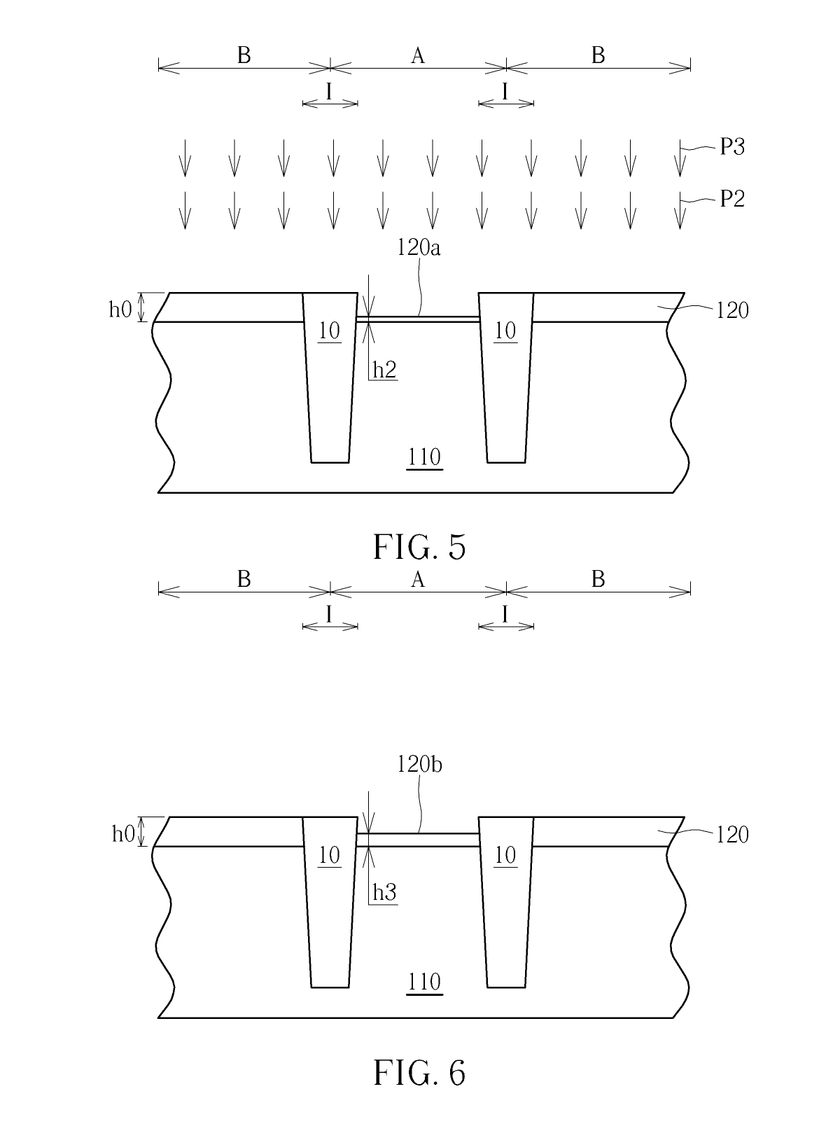

As shown in FIG. 6, the first gate oxide layer 120a of the first area A is thickened, and a second gate oxide layer 120b of the first area A having a second predetermined thickness h3 is formed. In this embodiment, only the first gate oxide layer 120a of the first area A is thickened while the thickness h0 of the first gate oxide layer 120 of the second areas B is maintained. In addition, the first gate oxide layer 120 of the second areas B may also be thickened while the first gate oxide layer 120a of the first area A is thickened. Preferably, the first gate oxide layer 120a is thickened by performing a non-nitrogen oxide process. It is noted that, since the first gate oxide layer 120a remains, oxides are more easily formed on the first gate oxide layer 120a than directly forming on the substrate 110. Therefore, nitrogen atoms, which are used to assist bonding, are not required while thickening the first gate oxide layer 120a, which means reliability of a formed device can be improved. Impurities of the formed second gate oxide layer 120b can be reduced and the mobility of the formed device can be improved. Still preferably, the first gate oxide layer 120a is thickened by performing a pure oxide process to reduce impurities and the mobility.

By applying the method of thinning the first gate oxide layer 120 and then thickening the first gate oxide layer 120a of the present invention, the second predetermined thickness h3 of second gate oxide layer 120b can be adjusted and controlled while thinning the first gate oxide layer 120 as well as thickening the first gate oxide layer 120a. This improves the accuracy and uniformity of the second predetermined thickness h3. Equivalent oxide thickness (EOT) and leakage current density (Jg) can also be reduced according to experimental data.

In practical circumstances, the second gate oxide layer 120b is 2˜3 angstroms thicker than the first gate oxide layer 120a and has the second predetermined thickness h3 of 7˜13 angstroms. This means the thickening from the first gate oxide layer 120a merely involves several angstrom thicknesses. For example, as the first predetermined thickness h2 of the first gate oxide layer 120a is 6 angstroms and the second predetermined thickness h3 of the second gate oxide layer 120b is 8 angstroms, the thickness is only increased by 2 angstroms thickness. The first gate oxide layer 120a is preferably thickened by performing a rapid thermal oxidation (RTO) process because of a slower oxide forming rate than other processes such as an in-situ steam generation (ISSG) process. The oxide forming rate can be controlled by adjusting an importing oxygen gas flow during the rapid thermal oxidation (RTO) process. In other embodiment, the first gate oxide layer 120a can be thickened by an in-situ steam generation (ISSG) process instead, which may comprise imported hydrogen gas and oxygen gas, depending upon practical requirements.

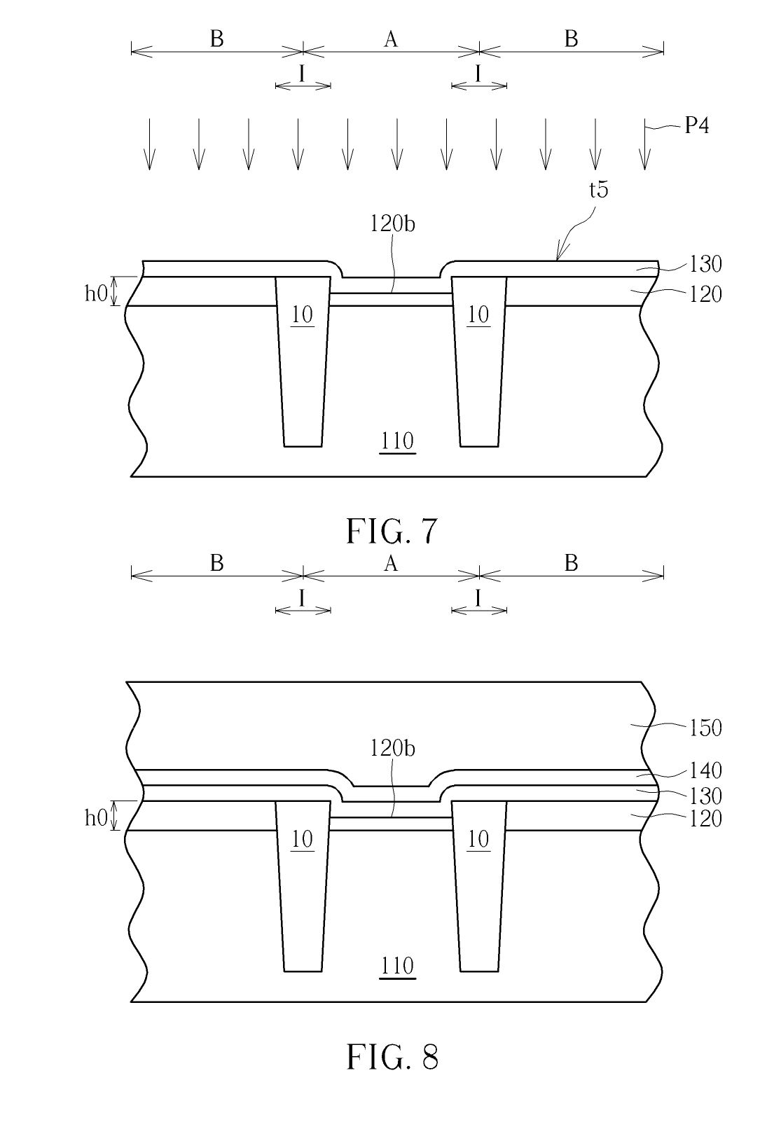

As shown in FIG. 7, a dielectric layer having a high dielectric constant 130 may be formed on the second gate oxide layer 120b of the first area A and the first gate oxide layer 120a of the second areas B. In this embodiment, the dielectric layer having a high dielectric constant 130 may be a hafnium oxide layer, but is not limited thereto. The dielectric layer having a high dielectric constant 130 may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO4), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST), but is not limited thereto. After the dielectric layer having a high dielectric constant 130 is formed, a decoupled plasma nitridation (DPN) process P4 may be optionally performed on the dielectric layer having a high dielectric constant 130 to nitride a top surface t5 of the dielectric layer having a high dielectric constant 130.

As shown in FIG. 8, a barrier layer 140 and a gate layer 150 may be sequentially formed on the dielectric layer having a high dielectric constant 130. The barrier layer 140 may be composed of titanium nitride, tantalum nitride, etc. The gate layer 150 may be composed of polysilicon, which may be replaced by metal layers in a metal gate replacement process performed later. Later semiconductor processes may be performed sequentially.

To summarize, the present invention provides a gate oxide formation process, which forms a first gate oxide layer on a substrate, thins the first gate oxide layer to a first predetermined thickness, and then thickens the first gate oxide layer to a second predetermined thickness. Thereby, a second gate oxide layer having the second predetermined thickness can be formed.

Since at least a part of the first gate oxide layer must remain after thinning; that is, the first predetermined thickness must be larger than zero, native oxide will not generate and divots of isolation structures contacting the remaining first gate oxide layer will not occur. Furthermore, the second predetermined thickness can be adjusted and controlled precisely, leading to better accuracy and uniformity. Equivalent oxide thickness (EOT) and leakage current density (Jg) can also be reduced.

Preferably, the first gate oxide layer is thickened by performing a non-nitrogen oxide process, so that impurities of the formed second gate oxide layer can be reduced and the mobility and reliability of the formed device can be improved. Still preferably, the first gate oxide layer 120a is thickened by performing a pure oxide process. The first gate oxide layer is preferably thickened by performing a rapid thermal oxidation (RTO) process because of a slower oxide forming rate than other processes such as an in-situ steam generation (ISSG) process, so that better thickness control is attainable.

Those skilled in the art will readily observe that numerous modifications and alterations of the device and method may be made while retaining the teachings of the invention. Accordingly, the above disclosure should be construed as limited only by the metes and bounds of the appended claims.

1: A gate oxide formation process, comprising:
forming a first gate oxide layer on a substrate;
thinning the first gate oxide layer to a first predetermined thickness being larger than zero; and
thickening the first gate oxide layer to a second predetermined thickness right after the first gate oxide layer is thinned, to thereby form a second gate oxide layer.

2: The gate oxide formation process according to claim 1, wherein the first gate oxide layer is thinned by performing an etching process.

3: The gate oxide formation process according to claim 2, wherein the etching process comprises an etchant of dilute hydrofluoric acid (DHF).

4: The gate oxide formation process according to claim 3, wherein the processing time of the etching process is in a range of 60˜80 seconds.

5: The gate oxide formation process according to claim 4, wherein the processing time of the etching process is 70 seconds.

6: The gate oxide formation process according to claim 1, wherein the first gate oxide layer is thickened by performing a non-nitrogen oxide process.

7: The gate oxide formation process according to claim 1, wherein the first gate oxide layer is thickened by performing a pure oxide process.

8: The gate oxide formation process according to claim 1, wherein the first gate oxide layer is thickened by performing a rapid thermal oxidation (RTO) process.

9: The gate oxide formation process according to claim 1, wherein the first gate oxide layer is thickened by performing an in-situ steam generation (ISSG) process.

10: The gate oxide formation process according to claim 9, wherein the in-situ steam generation (ISSG) process has imported hydrogen gas and oxygen gas.

11: The gate oxide formation process according to claim 1, wherein the first predetermined thickness is 5˜10 angstroms.

12: The gate oxide formation process according to claim 1, wherein the second predetermined thickness is 7˜13 angstroms.

13: The gate oxide formation process according to claim 1, wherein the first gate oxide layer is formed by performing an in-situ steam generation (ISSG) process.

14: The gate oxide formation process according to claim 13, wherein the in-situ steam generation (ISSG) process has imported hydrogen gas and oxygen gas.

15: The gate oxide formation process according to claim 1, further comprising:
forming a dielectric layer having a high dielectric constant on the second gate oxide layer after the second gate oxide layer is formed.

16: The gate oxide formation process according to claim 15, further comprising:
performing a decoupled plasma nitridation (DPN) process after the dielectric layer having a high dielectric constant is formed.

17: The gate oxide formation process according to claim 1, further comprising:
performing a cleaning process on the first gate oxide layer before the first gate oxide layer is thickened.

18: The gate oxide formation process according to claim 1, wherein the substrate comprises a first area and a second area, the first gate oxide layer is formed on both the first area and the second area, and then the first gate oxide layer is thinned and thickened only on the first area.

19: The gate oxide formation process according to claim 18, wherein the first area is a logic area while the second area is an input/output area.

20: The gate oxide formation process according to claim 18, further comprising:
forming an isolation structure between the first area and the second area to isolate the first area and the second area before the first gate oxide layer is formed, wherein a sidewall of the first gate oxide layer contacts a sidewall of the isolation structure.
